(19) United States
(12) Patent Application Publication
(10) Pub. No.: US 2026/0185220 A1
(43) Pub. Date: Jul. 2, 2026

(54) SOLID SOURCE VESSELS AND METHODS OF MONITORING

(71) Applicant: ASM IP Holding B.V., Almere (NL)

(72) Inventors: Arjav Vashi, Tempe, AZ (US); Shubham Garg, Gilbert, AZ (US)

(21) Appl. No.: 19/432,315

(22) Filed: Dec. 24, 2025

Related U.S. Application Data
(60) Provisional application No. 63/739,389, filed on Dec. 27, 2024.

(51) Int. Cl. C23C 16/448; C23C 16/52; G01G 19/52

(52) U.S. Cl. CPC C23C 16/448; G01G 19/52; C23C 16/52

(57) ABSTRACT

A method can comprise heating a source vessel comprising a solid precursor to a predetermined temperature; subliming a first portion of the solid precursor in the source vessel to produce a precursor gas; flowing the precursor gas through a gas line connecting the source vessel with a destination vessel; measuring, by a first pressure sensor coupled to the gas line, a pressure value of the precursor gas flowing through the gas line; and/or determining a first amount of the solid precursor that flowed from the source vessel to the destination vessel based on the pressure value. Determining the first amount of the solid precursor can comprise inputting the measured pressure value into a predetermined function of pressure versus precursor transfer rate.

### CROSS-REFERENCE TO RELATED APPLICATIONS

This application is a nonprovisional of, and claims priority to and the benefit of, U.S. Provisional Patent Application No. 63/739,389, filed Dec. 27, 2024 and entitled “SOLID SOURCE VESSELS AND METHODS OF MONITORING,” which is hereby incorporated by reference herein.

### FIELD OF THE DISCLOSURE

The present disclosure relates generally to semiconductor processing equipment and specifically to methods, systems, and apparatus for refilling a chemical precursor vessel.

### BACKGROUND OF THE DISCLOSURE

Semiconductor manufacturing processes such as chemical vapor deposition (CVD) and atomic layer deposition (ALD) involve deposition of thin film on a semiconductor wafer (also referred to herein as a “substrate”). During processing, the wafer is exposed to one or more precursors in a reaction chamber to deposit the thin layers of material. The precursor source is typically stored in a delivery vessel, which can be refilled from a refill vessel. However, because of the structure and/or component arrangement of a reactor system, it can be difficult to determine how much precursor has been transferred between vessels (e.g., from a refill vessel to a delivery vessel). Accordingly, methods of providing and monitoring the amount of precursor in, or delivered to or from, a vessel (e.g., a delivery vessel and/or refill vessel) can be important for process accuracy and maintenance, and/or to reduce the need to disassemble, remove, and/or service a vessel from a reactor system.

### SUMMARY OF THE DISCLOSURE

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

Systems and methods are disclosed relating to a reactor system. In various examples, a reactor system can comprise a source vessel comprising a solid precursor; a destination vessel fluidly coupled to the source vessel via a gas line such that a precursor gas sublimed from the solid precursor can flow from the source vessel to the destination vessel; and/or a pressure sensor coupled to the gas line configured to measure a pressure of the precursor gas flowing through the gas line. A destination vessel can comprise a vessel body and/or a vessel lid coupled to the vessel body. The lid can comprise a chemical inlet disposed in a central region of the lid. The reactor system can further comprise a heater in thermal communication with the lid, and/or a cooling device in thermal communication with a base portion of the vessel body.

In various examples, a method can comprise heating a source vessel comprising a solid precursor to a predetermined temperature; subliming a first portion of the solid precursor in the source vessel to produce a precursor gas; flowing the precursor gas through a gas line connecting the source vessel with a destination vessel; measuring, by a first pressure sensor coupled to the gas line, a pressure value of the precursor gas flowing through the gas line; and/or determining a first amount of the solid precursor that flowed from the source vessel to the destination vessel based on the predetermined temperature and/or the pressure value. Determining the first amount of the solid precursor can comprise inputting the pressure value into a predetermined function. In various examples, measuring the pressure value can comprise receiving, by a processor, a first pressure from the first pressure sensor; receiving, by the processor, a second pressure from a second pressure sensor coupled to the gas line; and/or calculating, by the processor, the pressure value based on the first pressure and the second pressure.

The predetermined function can be established by conducting a plurality of cycles to measure pressure and/or precursor transfer. A cycle of the plurality of cycles can comprise a series of steps (any one or combination of which can be completed by, or with the contribution from, a processor). The steps can include determining a starting weight of a test source vessel comprising the solid precursor; heating the test source vessel comprising the solid precursor to the predetermined temperature; subliming a test portion of the solid precursor in the test source vessel to produce the precursor gas; flowing the precursor gas through a test gas line connecting the test source vessel with a test destination vessel; measuring, by a test pressure sensor coupled to the test gas line, a test pressure of the precursor gas flowing through the test gas line; after ceasing the flowing the precursor gas, weighing the test source vessel to determine a first weight; determining a transferred amount of the solid precursor by comparing the first weight to the starting weight; plotting a data point based on the transferred amount and the test pressure on a pressure versus precursor transfer rate plot; and/or repeating the cycle (wherein the first weight becomes the starting weight of the test source vessel for subsequent cycles), to receive a plurality of (at least two) data points. The method can further comprise creating the predetermined function from the plurality of data points. The predetermined function can be linear. The predetermined function can be based on the solid precursor, the predetermined temperature, and/or a volume of the test source vessel. The test source vessel, test destination vessel, test pressure sensor, and/or test gas line can be the same components as, or similar or substantially identical to, the source vessel, destination vessel, pressure sensor, and/or gas line, respectively, comprised in the reactor system.

In various examples, the reactor system can further comprise a processor coupled to the pressure sensor; and/or a tangible non-transitory computer readable memory configured to communicate with the processor, the tangible non-transitory computer readable memory having instructions stored thereon that, in response to execution by the processor causes the processor to perform operations. The operations can comprise heating a source vessel comprising a solid precursor to a predetermined temperature; subliming a first portion of the solid precursor in the source vessel to produce a precursor gas; flowing the precursor gas through a gas line connecting the source vessel with a destination vessel; measuring, by a pressure sensor coupled to the gas line, a pressure value of the precursor gas flowing through the gas line; and/or determining a first amount of the solid precursor that flowed from the source vessel to the destination vessel based on the pressure value. The operations can further comprise inputting the pressure value into a predetermined function to determine the first amount of the solid precursor. The predetermined function can be based on a type of the solid precursor, a predetermined temperature (e.g., the predetermined temperature to which the source vessel was heated), and/or a volume of the source vessel. In various examples, the pressure sensor can be a first pressure sensor, wherein the reactor system can further comprise a second pressure sensor coupled to the gas line. The first pressure sensor can be coupled to the gas line proximate the source vessel, and the second pressure sensor can be coupled to the gas line proximate the destination vessel. Measuring the pressure value can comprise receiving, by the processor, the first pressure from the first pressure sensor; receiving, by the processor, a second pressure from the second pressure sensor; and/or calculating, by the processor, the pressure value based on the first pressure and the second pressure.

The predetermined function can be established by conducting a plurality of cycles to measure pressure and/or precursor transfer. The operations of the processor can further comprise conducting such cycles. A cycle can include determining a starting weight of a test source vessel comprising the solid precursor; heating the test source vessel comprising the solid precursor to the predetermined temperature to sublime a test portion of the solid precursor in the test source vessel to produce the precursor gas flowing through a test gas line to a test destination vessel; measuring a test pressure of the precursor gas flowing through the test gas line; after ceasing the flowing the precursor gas, determining a first weight of the test source vessel; comparing the first weight to the starting weight; determining a transferred amount of the solid precursor based on the comparing the first weight to the starting weight; and/or plotting a data point based on the transferred amount and the measured test pressure on a pressure versus precursor transfer rate plot. One or more of the steps in a cycle can be repeated in subsequent cycles to receive and plot a plurality of data points. The first weight of a previous cycle can become the starting weight of the test source vessel for a subsequent cycle. The operations can further comprise creating the predetermined function from the plurality of data points. The predetermined function can be linear. The test source vessel, test destination vessel, test pressure sensor, and/or test gas line can be the same components as, or similar or substantially identical to, the source vessel, destination vessel, pressure sensor, and/or gas line, respectively, comprised in the reactor system.

For the purpose of summarizing the disclosure and the advantages achieved over the prior art, certain objects and advantages of the disclosure have been described herein above. Of course, it is to be understood that not necessarily all such objects or advantages may be achieved in accordance with any particular example of the disclosure. Thus, for example, those skilled in the art will recognize that the disclosure may be embodied or carried out in a manner that achieves or optimizes one advantage or group of advantages as taught or suggested herein.

All of these examples are intended to be within the scope of the disclosure herein disclosed. These and other examples will become readily apparent to those skilled in the art from the following detailed description of certain examples having reference to the attached figures, the disclosure not being limited to any particular example(s) disclosed.

### BRIEF DESCRIPTION OF THE DRAWING FIGURES

These and other features, aspects, and advantages disclosed herein are described below with reference to the drawings of certain examples, which are intended to illustrate and not to limit the claimed subject matter. Elements with the like element numbering throughout the figures are intended to be the same.

FIG. 1 is a schematic diagram of a reactor system, in accordance with various examples.

FIG. 2A is a top perspective view of a precursor vessel for a reactor system, in accordance with various examples.

FIG. 2B is a top view of the precursor vessel of FIG. 2A, in accordance with various examples.

FIG. 3A is a top perspective view of the precursor vessel of FIGS. 2A and 2B including valves, in accordance with various examples.

FIG. 3B is a top view of the precursor vessel of FIG. 3A, in accordance with various examples.

FIG. 4 depicts a plot including data points and a function of pressure versus precursor transfer rate, in accordance with various examples.

FIG. 5 is a block diagram illustrating a method of determining a function of pressure versus precursor transfer rate, in accordance with various examples.

FIG. 6 is a block diagram illustrating a method of determining chemical precursor transfer, in accordance with various examples.

It will be appreciated that elements in the figures are illustrated for simplicity and clarity and have not necessarily been drawn to scale. For example, the relative size of some of the elements in the figures may be exaggerated relative to other elements to help improve understanding of illustrated examples of the present disclosure.

### DETAILED DESCRIPTION

The description of examples of methods, structures, devices, and systems provided below is merely exemplary and is intended for purposes of illustration only—the following description is not intended to limit the scope of the disclosure or the claims. Moreover, recitation of multiple examples having stated features is not intended to exclude other examples having additional features or other examples incorporating different combinations of the stated features. For example, various examples are set forth as embodiments and may be recited in the dependent claims. Unless otherwise noted, the examples or components thereof may be combined or may be applied separately from each other. Methods may include the disclosed steps in any suitable and/or desired order or combination.

As used herein, the term “and/or” includes any and all combinations of one or more of the associated listed items. Unless otherwise noted, expressions such as “at least one of,” when preceding a list of elements, modify the entire list of elements and do not necessarily modify the individual elements of the list.

As used herein, the terms “includes,” “comprises,” “including,” and/or “comprising” specify the presence of stated features, integers, steps, processes, members, components, and/or groups thereof, but do not preclude the presence or addition of one or more other features, integers, steps, processes, members, components, and/or groups thereof. In this disclosure, any defined meanings do not necessarily exclude ordinary and customary meanings in some examples.

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

In some examples, “film” refers to a layer extending in a direction perpendicular to a thickness direction. In some examples, “layer” refers to a material having a certain thickness formed on a surface and can be a synonym of a film or a non-film structure. A film or layer may be constituted by a discrete single film or layer having certain characteristics or multiple films or layers, and a boundary between adjacent films or layers may or may not be clear and may or may not be established based on physical, chemical, and/or any other characteristics, formation processes or sequence, and/or functions or purposes of the adjacent films or layers. The layer or film can be continuous—or not. Further, a single film or layer can be formed using one or more deposition cycles and/or one or more deposition and treatment cycles.

As used herein, the term “structure” can refer to a partially or completely fabricated device structure. By way of examples, a structure can be a substrate or include a substrate with one or more layers and/or features formed thereon.

As used herein, the term “cyclical” deposition or etch process or “cyclic” deposition or etch process can refer to a vapor deposition process in which deposition or etch cycles, typically a plurality of consecutive deposition or etch cycles, are conducted in a process chamber. Cyclic deposition or etch processes can include, for example, cyclic chemical vapor deposition (CCVD) and/or atomic layer deposition (ALD) processes. Cyclic deposition or etch processes can include plasma-enhanced steps. A cyclic deposition or etch process can include one or more cycles that include plasma activation of a precursor, a reactant, and/or an inert gas in any combination.

In this disclosure, any two numbers of a variable can constitute a workable range of the variable, any ranges indicated may include or exclude the endpoints, and all ranges and ratio limits disclosed herein may be combined. Additionally, any values of variables indicated (regardless of whether they are indicated with “about” or not) may refer to precise values or approximate values and include equivalents, and may refer to average, median, representative, majority, etc. in some examples. Unless specifically stated otherwise, references to “a,” “an,” and/or “the” may include one or more than one, and references to an item in the singular may also include the item in the plural. When referring to components of systems discussed herein, the term “coupled” refers to direct coupling or indirect coupling with other intervening elements, as appropriate. Unless otherwise indicated, the terms “first,” “second,” etc., and/or “primary,” “secondary,” etc., are used herein merely as labels, and are not intended to impose ordinal, positional, or hierarchical requirements on the items to which these terms refer. Moreover, reference to, e.g., a “second” item does not require or preclude the existence of, e.g., a “first” or lower-numbered item, and/or, e.g., a “third” or higher-numbered item. Further, reference to, e.g., a “first” item and a “second” item does not mean that there are no intervening items, and such intervening items may be present.

Reactor systems used for ALD, CVD, and/or the like, may be used for a variety of applications, including depositing and etching materials on a substrate surface. A reactor system can comprise a precursor vessel (i.e., delivery vessel), in which a chemical precursor can be stored, and from which the chemical precursor can be delivered to another component of the reactor system (e.g., a reaction chamber) for processing. The precursor vessel can comprise a solid source vessel configured to house a solid precursor (e.g., “precursor vessel,” “delivery vessel,” and/or “solid source vessel” may be used interchangeably herein).

The delivery vessel can include the source precursor (which may also be referred to as “reactant,” “chemical,” or “chemical precursor”), which can be a solid (e.g., in powder form) or liquid. A heater (e.g., a radiant heat lamp, resistive heater, and/or the like) coupled to and/or in thermal communication with the delivery vessel can heat up the delivery vessel to facilitate the vaporization and/or sublimation of the chemical precursor in the delivery vessel. The delivery vessel can have an inlet and an outlet for the flow of a carrier gas through the delivery vessel. The carrier gas can be inert, for example, nitrogen, argon, or helium. Generally, the carrier gas conveys reactant vapor (e.g., evaporated or sublimed chemical reactant) along with it through the vessel outlet and ultimately to a substrate reaction chamber. In various examples, a delivery vessel comprises, consists essentially of, or consists of a sublimator. As such, wherever a “solid source vessel” is mentioned herein, a sublimator (such as a “solid source chemical sublimator”) is also contemplated.

In various examples, each reactant gas can be stored in a delivery vessel. The reactants can be gaseous at standard pressures and temperatures of around 1 atmosphere and room temperature. Examples of such gases include nitrogen, oxygen, hydrogen, and ammonia. In various examples, the vapors of precursors that are liquid or solid (e.g., hafnium chloride, hafnium oxide, zirconium dioxide, etc.) at standard pressure and temperature are used. For some solid substances (referred to herein as “solid source precursors,” “solid precursors,” “solid chemical reactants,” “solid reactants,” or the like), the vapor pressure at room temperature is so low that they are typically heated and/or maintained at very low pressures to produce a sufficient amount of reactant vapor for the reaction process. Vapor phase reactants from solid or liquid substances can be useful for chemical reactions in a variety of industries.

One or more remote refill vessels may be included in a reactor system for filling a delivery vessel with source precursor as described herein. As used herein, a remote refill vessel can be described as a “source vessel,” and the precursor or delivery vessel can be described as a “destination vessel” (that is, the remote refill vessel can be the source of refill precursor, and a delivery vessel can be the destination of the refill precursor). Conventionally, delivery vessels are removed and refilled from a reactor system, which can lead to downtime and a loss of wafer production. The remote refill vessels can reduce a need to replace or refill a sublimator. Instead, the remote refill vessels can be used to automatically and/or continuously supply a delivery vessel with chemicals such as source precursor. A remote refill vessel system may include one or more remote refill vessels. In various examples, a remote refill vessel may be disposed in a location that is spaced apart from other reactor system components. For example, a remote refill vessel can be located in another room from, across a cleanroom from, and/or adjacent to other reactor system components.

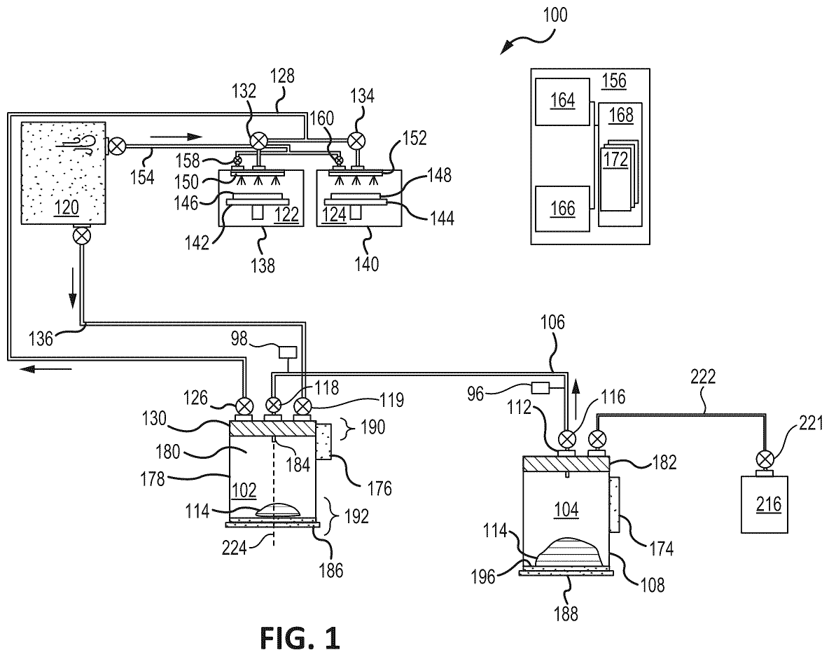

FIG. 1 is a schematic illustrating an example reactor system 100 including a delivery vessel 102 and/or one or more reactors 138 and 140 including respective reaction chambers 122 and 124. Reactors 138 and 140 can include respective susceptors 142 and 144 to hold respective substrates 146 and 148 during processing and gas distribution systems 150 and 152 to distribute one or more reactants/precursors to respective surfaces of substrates 146 and 148. Reactor system 100 can include a vacuum source for controlling vacuum pressure in one or more of reaction chambers 122 and 124. A reactant source can feed a gas-phase reactant, generated from a solid source delivery vessel 102 into gas-phase reactors. Reactors 138 and/or 140 can be gas-phase reactors. Solid source delivery vessel 102 can contain chemical 114 (e.g., in a solid state). The solid chemical can comprise a chemical reactant including, for example, HfCl₄, ZrCl₄, AlCl₃, TaF₅, MoF₅, and/or SiI₄. Chemical 114 can be solid under standard conditions (i.e., room temperature and atmospheric pressure).

A carrier gas source 120 can be coupled to delivery vessel 102 via carrier gas line 136 and can hold a carrier gas. Lid 130 of delivery vessel 102 can comprise a carrier gas valve 119 to regulate flow of the carrier gas from carrier gas source 120 into delivery vessel 102. Carrier gas source 120 can be fluidly coupled to reaction chambers 122 and 124 via gas line 154 and valves 158 and 160. In various examples, valves 158 and 160 can be controlled by one or more controllers. In response to being introduced into delivery vessel 102, the carrier gas can help transport vaporized and/or sublimed chemical reactants through vessel outlet valve 126 to reaction chamber 122 and/or 124. Chemical delivery line 128 can comprise valves 132 and 134 for controlling fluid communication of chemical 114 and/or carrier gas from delivery vessel 102 to respective reaction chambers 122 and 124.

In various examples, delivery vessel 102 may be coupled to a remote refill vessel 104 via a chemical refill gas line 106. Remote refill vessel 104 may be located a distance from delivery vessel 102 and/or any other component of reactor system 100 (e.g., in a different room and/or on a different plane than delivery vessel 102, reaction chambers 122, 124, and/or the like).

Remote refill vessel 104 may contain refill chemical 114 comprising a precursor or source chemical, which may be solid under standard conditions (i.e., room temperature and atmospheric pressure). Chemical 114 in remote refill vessel 104 can be the same as chemical 114 in delivery vessel 102. Remote refill vessel 104 can be a bulk refill container that can have a larger chemical capacity within housing 108 than delivery vessel 102 (e.g., because remote refill vessel 104 may not be restrained by dimension restrictions associated with other components of reactor system 100). For example, remote refill vessel 104 can have at least 1.5×, 2×, 3×, 4×, 5×, 10×, or 20× the capacity of delivery vessel 102.

Chemical refill gas line 106 can extend between outlet valve 116 of remote refill vessel 104 and inlet valve 118 of delivery vessel 102. Inlet valve 118 can be disposed in lid 130 of delivery vessel 102. Outlet valve 116 can be disposed in lid 182 of remote refill vessel 104. Outlet valve 116 and inlet valve 118 can control fluid communication of chemical 114 from remote refill vessel 104 to delivery vessel 102.

Remote refill vessel 104 can be equipped to vaporize (e.g., sublime, evaporate) chemical 114 and can pass vaporized or sublimed chemical 114 to delivery vessel 102 via chemical refill gas line 106. In various examples, remote refill vessel 104 can be coupled to, and/or proximate, a heating device 174 disposed exterior to and in thermal communication with lid 182 and/or housing 108. Housing 108 can be made of a thermally conductive material (e.g., stainless steel) and can be configured to transfer heat from heating device 174 to a lid 182 and/or an interior volume of remote refill vessel 104. Heating device 174 can be configured to heat chemical 114 to a temperature sufficient to change the phase of chemical 114, such as to vaporize and/or sublime chemical 114 in order to transfer chemical 114 via chemical refill gas line 106 to delivery vessel 102. Heating device 174 can comprise any suitable heating device (e.g., a heater, heating jacket, heating block, radial heater, and/or the like).

Remote refill vessel 104 can be configured to store chemical 114 between refill operations (e.g., in a solid state). A cooling device 188 can be coupled to a bottom portion of remote refill vessel 104. Cooling device 188 can cool base portion 196 of remote refill vessel 104 to maintain chemical 114 in solid form prior to sublimation. Cooling device 188 can comprise a chill plate, cooling coils, variable pitch cooling coils, a cooling jacket, cooling fans, a Peltier cooler or integrated coolant channels circulating coolant or the like or any combination thereof.

Remote refill vessel 104 can be configured to operate at a selected temperature. For example, the operating temperature may be determined based on a desired subliming rate of the chemical precursor/reactant. In some examples, the operating temperature is in the range of about 10° C. to about 500° C. The selected operating temperature can depend upon the chemical to be vaporized or sublimed.

Delivery vessel 102 can receive chemical 114 in gas phase via chemical refill gas line 106 from remote refill vessel 104. Chemical refill gas line 106 can be disposed at the top portion 190 of delivery vessel 102, for example, in lid 130. In various examples, lid 130 and inlet valve 118 can be configured to liquify chemical 114 as it passes into delivery vessel 102 so as to cause liquified chemical 114 to drip, for example from inlet 184, to the bottom of delivery vessel 102 to solidify.

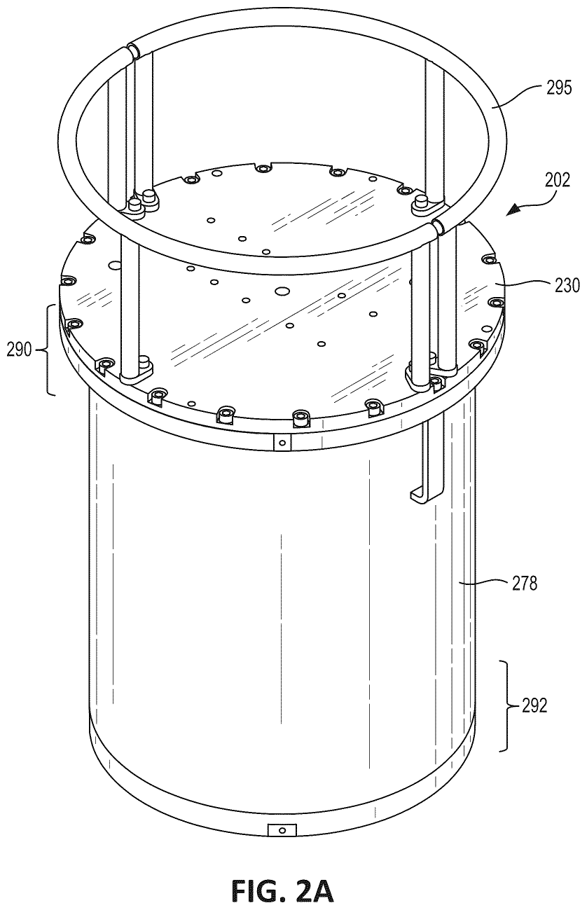

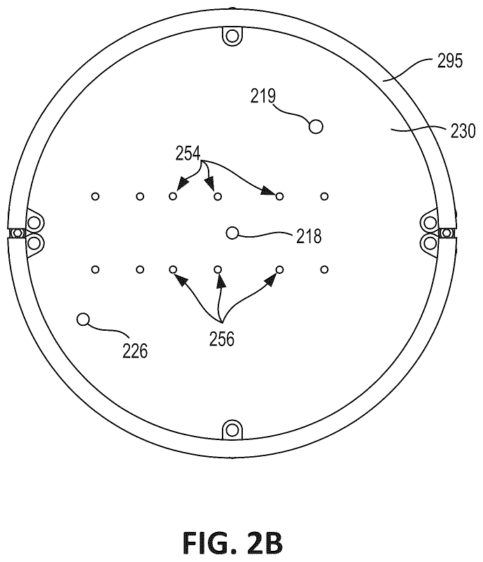

Delivery vessel 102 can comprise any suitable structure and/or configuration to perform the functions discussed herein. With additional reference to FIGS. 2A and 2B, delivery vessel 202 is an example of delivery vessel 102 (discussed in relation to FIG. 1). Delivery vessel 202 can comprise a vessel body 278 (an example of vessel body 178 of delivery vessel 102), spanning between a top portion 290 (an example of top portion 190 of delivery vessel 102) and a base portion 292 (an example of base portion 192 of delivery vessel 102). A lid 230 (an example of lid 130 of delivery vessel 102) can be coupled to vessel body top portion 290, enclosing an interior volume of delivery vessel 202. A removable handle 295 can be coupled to delivery vessel 202 (e.g., coupled to vessel body 278 and/or lid 230) configured to aid in transporting or moving delivery vessel 202.

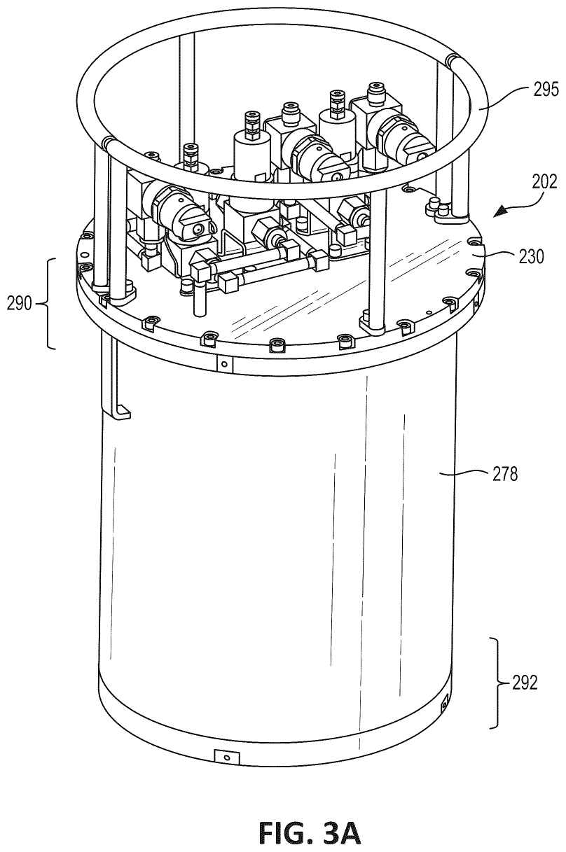

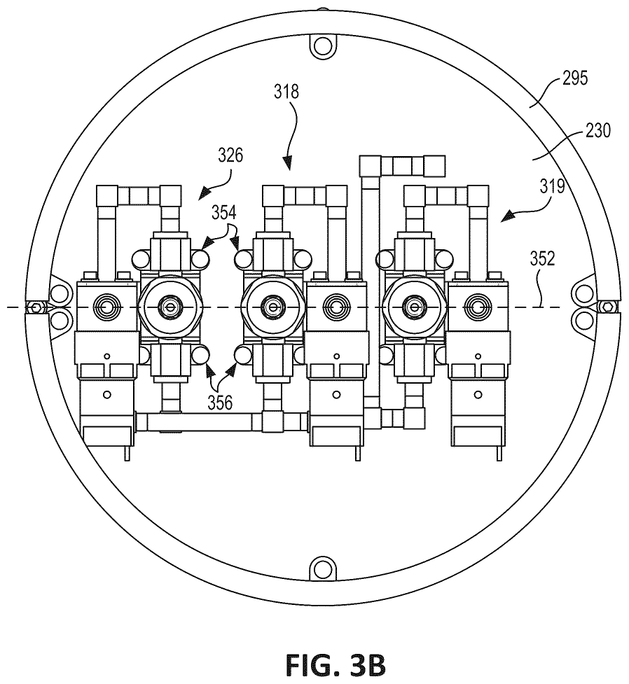

Lid 230 of delivery vessel 202 can comprise a chemical inlet 218, carrier gas inlet 219, and/or chemical outlet 226. Chemical inlet 218 can be configured to receive a chemical precursor from a remote refill vessel (e.g., chemical inlet 218 can have an inlet valve 118 coupled thereto configured to receive a chemical precursor from remote refill vessel 104). Chemical inlet 218 can be disposed in a central region of lid 230 (a central region can be the central 10% or 20%, including the center point of lid 230). Such a position of chemical inlet 218 can allow chemical precursor being received from a remote refill vessel to enter the interior volume of vessel body 278 and be distributed therein more evenly than a chemical inlet disposed in another position. Chemical outlet 226 can be configured to pass precursor therethrough out of delivery vessel 202 toward a reaction chamber (e.g., reaction chamber 122 and/or 124). Carrier gas inlet 219 can be configured to allow carrier gas into delivery vessel 202 (e.g., from carrier gas source 120). Coupling points 254 and 256 can be configured to facilitate the coupling of valves to lid 230 (e.g., as shown in FIG. 3B).

With additional reference to FIGS. 3A and 3B, delivery vessel 202 can comprise valves coupled to the respective inlets in lid 230. For example, inlet valve 318 (an example of inlet valve 118) can be fluidly coupled to chemical inlet 218, outlet valve 326 (an example of outlet valve 126) can be fluidly coupled to chemical outlet 226, and/or carrier gas valve 319 (an example of carrier gas valve 119) can be coupled to carrier gas inlet 219. Coupling points 354 and 356 on the respective valves can be complementary to coupling points 254, 256 on lid 230 to facilitate coupling between the valves and lid 230. The coupling points and valves on lid 230 can be disposed linearly along and/or parallel to an axis 352.

Delivery vessel 102 can be thermally coupled to one or more heating devices 176 (e.g., heaters, heating jackets, heating blocks, and/or radial heater) and/or one or more cooling devices 186. Such heating or cooling devices can serve to control or adjust the temperature of chemical 114 during refilling operations, material processing operations, and/or storage of chemical 114. Cooling devices 186 can comprise, a chill plate, cooling coils, variable pitch cooling coils, a cooling jacket, cooling fans, a Peltier cooler, and/or integrated coolant channels circulating coolant. As discussed in more detail herein, such heating and cooling devices 186 provide a temperature gradient within delivery vessel 102.

In various examples, heating device 176 can be coupled to and/or in thermal communication with delivery vessel 102 (e.g., at vessel body 178 (e.g., a housing) and/or lid 130). Vessel body 178 and/or lid 130 can be configured to transfer heat and/or pressure from heating device 176 to chemical 114 (e.g., as it enters delivery vessel 102, and/or to evaporate or sublime chemical 114 for flowing through chemical delivery line 128). Such applied heat and/pressure can liquify chemical 114 causing it to form droplets and fall to the bottom of delivery vessel 102. Delivery vessel 102 base portion 192 can be cooled by a cooling device 186 (e.g., a cold plate) to a lower temperature than chemical refill gas line 106, sidewalls of vessel body 178, and/or lid 130 of delivery vessel 102. This can provide a temperature gradient along longitudinal axis 224 where the highest temperature in the system can be at the top portion 190 of delivery vessel 102 and the lowest temperature in the system can be at the base 192. Liquid droplets of chemical 114 can form as chemical 114 enters through lid 130 and can solidify in response to contact with bottom surface at the base 192 of delivery vessel 102. During refill (transferring chemical 114 from remote refill vessel 104 to delivery vessel 102), chemical 114 can form a solid at the bottom of delivery vessel 102 and may be stored there until a material processing operation. Cooling device 186 can maintain a temperature at base 192 of delivery vessel 102 sufficient to maintain chemical 114 in solid phase.

During a refilling operation, delivery vessel 102 can be configured to operate with a temperature gradient within the interior volume 180. For example, the operating temperature proximate top portion 190 may be determined based on a desired liquification rate of chemical 114 precursor/reactant. In some examples, the operating temperature is in the range of about 10° C. to about 500° C. The selected operating temperature can depend upon the chemical to be liquified as it enters delivery vessel 102. Likewise, delivery vessel 102 base 192 can be maintained at a lower temperature than the top portion 190 to solidify chemical 114 on base 192 to maintain the temperature gradient within delivery vessel 102. The selected operating base temperature can depend upon the chemical to be solidified. Additionally, to prevent gaseous particles from solidifying in unwanted areas on the interior of delivery vessel 102, base 192 may be set to a temperature that is at least cooler than top portion 190. In various examples, base 192 is the coolest location in the interior volume 180 of delivery vessel 102. Thus, the operating temperature at base 192 may be well below a melting point of chemical 114.

The temperature gradient extends between the base 192 and top portion 190 including lid 130. In various examples, base 192 can be maintained at or below a first threshold temperature, while top portion 190 can be maintained at or above a second threshold temperature that is greater than the first threshold temperature. In various examples, the difference in temperature between the base 192 and portion 190 can be at least about 1° C., about 5° C., about 10° C., about 20° C., about 40° C., about 80° C., or about 160° C., or any value therebetween, or fall within any range having endpoints therein.

In various examples, during a material processing operation, heating device 176 can be configured to heat chemical 114 to a temperature sufficient to change the phase of chemical 114, such as to vaporize and/or sublime chemical 114. Once vaporized or sublimed, chemical 114 can be transported via chemical delivery line 128 to reaction chambers 122 and/or 124 for substrate processing. Prior to vaporization and/or sublimation, chemical 114 may be stored as a solid in delivery vessel 102. Alternatively, chemical 114 may be stored in liquid phase during or after refilling. Heating device 176 may be configured to heat delivery vessel 102 to a temperature sufficient to liquify chemical 114.

During material processing, delivery vessel 102 can be configured to operate at a selected temperature based on a desired subliming rate of chemical 114 precursor/reactants. In some examples, the operating temperature is in the range of about 10° C. to about 500° C.

Delivery vessel 102 can be refilled from remote refill vessel 104. As depicted in FIG. 1, reactor system 100 comprises controller 156, which includes a processor 164, a user interface 166, and/or a memory 168. Processor 164 can be operably connected to user interface 166 (e.g., to receive user input and/or provide user output therethrough) and can be disposed in communication with memory 168. Memory 168 includes a tangible, non-transitory, machine-readable medium having a plurality of program modules/instructions 172 stored thereon that, in response to reading and/or execution by processor 164, cause processor 164 to execute certain operations. Among the operations are operations of a material layer deposition method, methods for refilling a delivery vessel 102, and/or methods for determining precursor transfer, as discussed herein. As will be appreciated by those of skill in the art in view of the present disclosure, the controller 156 may have a different arrangement in other examples and remain within the scope of the present disclosure.

In some examples, a carrier gas source 216 may be coupled to remote refill vessel 104 via chemical delivery line 222 and may supply carrier gas to remote refill vessel 104. Valve 221 may control the flow of carrier gas 220. Carrier gas 220 may assist transport of the sublimated chemical 114 from the remote refill vessel 104 to delivery vessel 102.

In various examples, the refilling process may be controlled manually and/or refill operations can be partially or fully automated, for example using one or more sensors for automated feedback controlled by controller 156. With continued reference to FIG. 1, reactor system 100 can comprise one or more pressure sensors (i.e., pressure transducers, transmitters, and/or the like) coupled to chemical refill gas line 106. For example, reactor system 100 can comprise a first pressure sensor 96 proximate remote refill vessel 104 and a second pressure sensor 98 proximate delivery vessel 102. That is, first pressure sensor 96 can be more proximate refill vessel 104 than second pressure sensor 98. Pressure sensors 96, 98 can be configured to measure a pressure within chemical refill gas line 106, for example, during a refill process transferring chemical precursor from remote refill vessel 104 to delivery vessel 102. Controller 156 and/or processor 164 can be in electronic communication (or operably coupled) with one or more of the pressure sensors, such that controller 156 and/or processor 164 can receive a pressure reading or data from the pressure sensors. In various examples, chemical refill gas line 106 can comprise an accumulator, and a pressure sensor can be coupled to the accumulator to measure the pressure therein.

Based on the pressure within chemical refill gas line 106 between remote refill vessel 104 and delivery vessel 102, an amount of chemical precursor (e.g., solid precursor) transfer can be determined. Thus, the amount of chemical precursor left within remote refill vessel 104 can also be determined based on pressure within chemical refill gas line 106. To do so, a function of pressure (e.g., equilibrium pressure) in chemical refill gas line 106 versus precursor transfer rate (e.g., grams per unit time, such as grams/hour) can be predetermined. The predetermined function can be used to determine a precursor transfer amount based on a measured pressure by inputting the measured pressure into the predetermined function, yielding an associated precursor transfer amount.

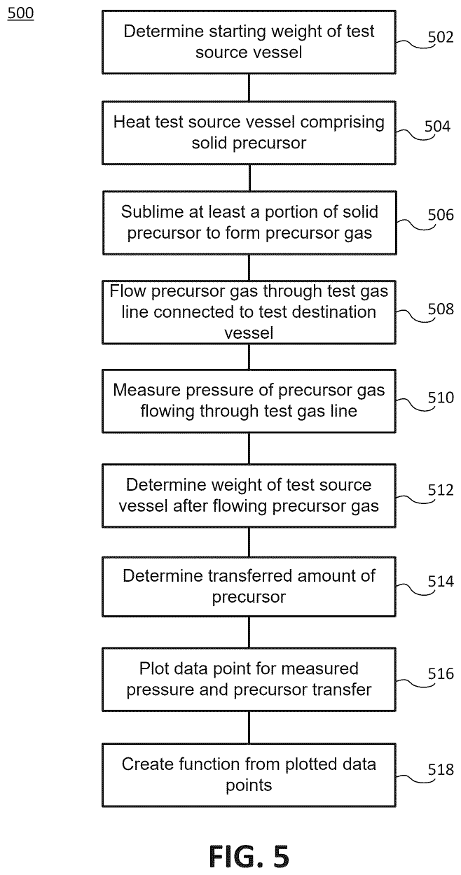

With additional reference to FIG. 5, a method 500 of determining a function (the predetermined function) of pressure versus precursor transfer rate is depicted. To do so, a starting weight of a test source vessel (e.g., remote refill vessel 104) can be determined (step 502). The test source vessel can be the source vessel used in reactor system 100, or a similar or substantially identical vessel to the source vessel used in a reactor system. The test source vessel can be weighed, which can require removal from reactor system 100, with solid chemical 114 disposed therein. The starting weight can be determined by a processor (e.g., processor 164), and/or received by the processor from a scale used to weigh the test source vessel. In various examples, the weight of the test source vessel can be tared before chemical 114 is added to the test source vessel to determine the weight of chemical 114 in the test source vessel.

The test source vessel can be fluidly coupled to a test destination vessel, for example via a test gas line. The test destination vessel can be the destination vessel used in reactor system 100 (e.g., delivery vessel 102), or a similar or substantially identical vessel to the destination vessel used in a reactor system. Similarly, the test gas line can be the gas line used in reactor system 100 (e.g., chemical refill gas line 106) between the source and destination vessels, or a similar or substantially identical gas line to that used in a reactor system. The test vessel can be heated (step 504) to a temperature sufficient to sublime at least a portion of the solid precursor therein to form a precursor gas (step 506). The temperature to which the test source vessel can be heated can be a predetermined temperature (e.g., the temperature that will be used during a refill event). Such heating can be completed by, for example, heating device 174 (e.g., in communication with a processor) in thermal communication with the test source vessel. In response to forming a precursor gas, the precursor gas can flow through the test gas line connected to the test destination vessel (step 508). The processor can cause one or more valves (e.g., outlet valve 116 from remote refill vessel 104 and/or inlet valve 118 of delivery vessel 102) to open to allow precursor gas to flow between vessels. During flowing the precursor gas through the test gas line, a pressure of the precursor gas within the test gas line can be measured (step 510). For example, pressure sensor 96 and/or 98 (e.g., in conjunction with a processor) can measure the pressure in the test gas line. The processor can receive the pressure readings from the pressure sensor(s). The pressure reading can be an equilibrium pressure in the test gas line. In various examples in which two or more pressure sensors are used (e.g., pressure sensors 96 and 98), a pressure value can be calculated using the multiple pressure readings (e.g., by averaging).

The flow of the precursor gas can be ceased (e.g., by the processor closing the appropriate valves). In response, a weight of the test source vessel can be determined (step 512). This can be a first or new weight of the test source vessel, after the starting weight. The test source vessel can be weighed (e.g., by the processor) to determine the weight. The test source vessel may require removal from its position in the reactor system to do so. The new weight of the test source vessel can be compared to the starting weight of the test source vessel (e.g., by the processor) to determine (e.g., by the processor) a transferred amount of solid precursor from the test source vessel (step 514). Based on the amount of time that the gas precursor was flowed between the test source vessel and the test destination vessel, a precursor transfer rate can be determined (e.g., grams per unit time, such as grams/hour). A data point comprising the measured pressure and the precursor transfer rate can be plotted (step 516) on a plot of pressure (equilibrium) vs. precursor transfer in grams per hour. To obtain more data points to add to such a plot, steps 502-516 can be repeated in any suitable order and/or arrangement. For example, the first, new weight determined in step 512, discussed above, can be the starting weight in step 502 in repeating the steps of method 500.

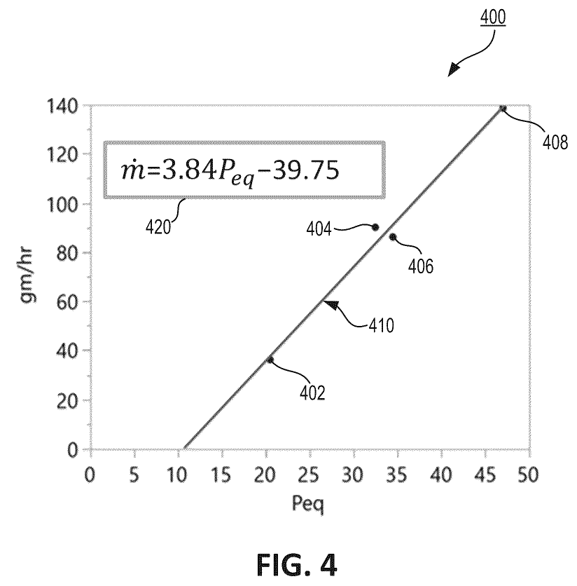

As shown in plot 400 of FIG. 4, four data points were obtained and plotted (e.g., utilizing the steps of method 500). For example, data point 402 comprises a pressure of about 20 torr and a precursor transfer rate of about 37 grams/hour, data point 404 comprises a pressure of about 32 torr and a precursor transfer rate of about 90 grams/hour, data point 406 comprises a pressure of about 34 torr and a precursor transfer rate of about 85 grams/hour, and data point 408 comprises a pressure of about 47 torr and a precursor transfer rate of about 139 grams/hour (as used in this context, the term “about” means plus or minus ten percent of the subject value). The units of pressure can be any suitable pressure unit (e.g., torr, pounds per square inch, pascal, atmospheres, millimeters of mercury, and/or the like).

From the plotted data points (e.g., data points 402-408), a function can be created (e.g., by the processor) (step 518). For example, based on data points 402-408 in plot 400, the processor can determine a function 420. Function 420 can be a predetermined function used to estimate/predict the precursor transfer rate and/or transfer amount based on a measured pressure in a gas line between the source and destination vessels (e.g., a pressure measurement from a pressure sensor). As shown in plot 400, function 420 can be linear (i.e., data points can be substantially plotted along line 410). That is, the relationship between pressure and precursor flow rate can be a linear relationship.

The predetermined function discussed herein can be specific to a certain or specific set of parameters (e.g., a certain chemical, source vessel volume, destination vessel volume, vessel material, temperature (e.g., the predetermined temperature), etc.). Thus, under the same set of parameters used to determine predetermined function 420, a measured pressure in a gas line between a source vessel and a destination vessel can be input into function 420, and an estimated precursor transfer rate can be determined, from which a precursor transfer amount can be determined. For another set of parameters (e.g., with a different chemical, vessel volume, vessel material, temperature, and/or the like), method 500 can be used to determine the predetermined function for that set of parameters.

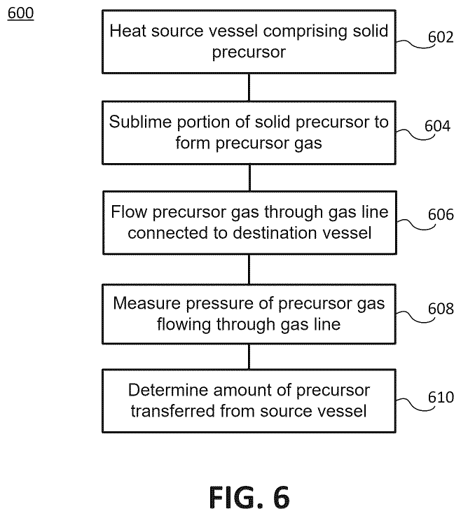

A method 600 for determining an amount of chemical precursor transfer (e.g., from a source vessel to a destination vessel) is depicted in FIG. 6. Method 600 can utilize a predetermined function, as discussed herein. As an example, the source vessel can be remote refill vessel 104 and the destination vessel can be delivery vessel 102 of reactor system 100 (FIG. 1). The source vessel comprising a solid precursor can be heated (step 602) to sublime at least a portion of the precursor to form precursor gas (step 604). Such heating can be completed by, for example, heating device 174 in thermal communication with the source vessel. In response to forming a precursor gas, the precursor gas can flow through chemical refill gas line 106 connected to the destination vessel (step 606). During flowing the precursor gas through chemical refill gas line 106, a pressure of the precursor gas within chemical refill gas line 106 can be measured (step 608). For example, pressure sensor 96 and/or 98 (e.g., in conjunction with a processor) can measure the pressure in chemical refill gas line 106. The processor can receive the pressure readings from the pressure sensor(s). The pressure reading can be an equilibrium pressure in chemical refill gas line 106. In various examples in which two or more pressure sensors are used (e.g., pressure sensor 96 and 98), a pressure value can be calculated using the multiple pressure readings (e.g., by averaging).

Based on the measured pressure, the amount of precursor transferred from the source vessel can be determined (e.g., estimated) (step 610). For example, the processor can receive the measured pressure of the gas precursor in chemical refill gas line 106 (e.g., from a pressure sensor). In response, the processor can input the measured pressure into the applicable predetermined function (e.g., predetermined function 420) to determine a precursor transfer rate (an estimate thereof). For example, utilizing predetermined function 420, for a pressure measurement of 30, precursor transfer rate of 75.45 grams/hour can be determined. A precursor transfer amount from the source vessel can be determined (e.g., by the processor) from the estimated precursor transfer rate based on the time the precursor gas was flowed through chemical refill gas line 106. Continuing with the example above, if precursor gas was flowed for one minute, 1.26 grams transferred from the source vessel.

Any or all of the steps of methods 500 or 600 can be performed by a processor comprised in the respective reactor system, as appropriate.

Utilizing the systems and methods discussed herein can allow estimation of the amount of chemical precursor that has been flowed from the source vessel (e.g., remote refill vessel 104) to the destination vessel (e.g., delivery vessel 102), without requiring disassembly or decoupling of reactor components (e.g., to weigh a vessel or take other action).

The structure and methods herein are discussed regarding delivery vessel 102 and remote refill vessel 104. However, it should be understood that the structures and methods discussed herein can be applied to any suitable vessel, and/or any suitable vessels having a gas line fluidly coupling the vessels for gas flow therebetween, and having a pressure sensor coupled to the gas line.

The examples of the disclosure described above do not limit the scope of the claimed subject matter, since these are merely examples. The invention is defined by the appended claims and their legal equivalents. Any equivalent embodiments are intended to be within the scope of this disclosure. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method, comprising:
heating a source vessel comprising a solid precursor to a predetermined temperature;
subliming a first portion of the solid precursor in the source vessel to produce a precursor gas;
flowing the precursor gas through a gas line connecting the source vessel with a destination vessel;
measuring, by a first pressure sensor coupled to the gas line, a pressure value of the precursor gas flowing through the gas line; and
determining a first amount of the solid precursor that flowed from the source vessel to the destination vessel based on the pressure value.

2. The method of claim 1, wherein the determining the first amount of the solid precursor comprises inputting the pressure value into a predetermined function.

3. The method of claim 2, wherein the predetermined function is determined by conducting a plurality of cycles, wherein a cycle of the plurality of cycles comprises:
determining a starting weight of a test source vessel comprising the solid precursor;
heating the test source vessel comprising the solid precursor to the predetermined temperature;
subliming a test portion of the solid precursor in the test source vessel to produce the precursor gas;
flowing the precursor gas through a test gas line connecting the test source vessel with a test destination vessel;
measuring, by a test pressure sensor coupled to the test gas line, a test pressure of the precursor gas flowing through the test gas line;
after ceasing the flowing the precursor gas, weighing the test source vessel to determine a first weight;
determining a transferred amount of the solid precursor by comparing the first weight to the starting weight;
plotting a data point based on the transferred amount and the measured pressure on a pressure versus precursor transfer rate plot;
repeating the cycle, wherein the first weight becomes the starting weight of the test source vessel, to receive a plurality of data points.

4. The method of claim 3, further comprising creating the predetermined function from the plurality of data points.

5. The method of claim 2, wherein the function is linear.

6. The method of claim 3, wherein the predetermined function is based on the solid precursor, the predetermined temperature, and a volume of the test source vessel.

7. The method of claim 1, wherein the measuring the pressure value comprises:
receiving, by a processor, a first pressure from the first pressure sensor;
receiving, by the processor, a second pressure from a second pressure sensor coupled to the gas line; and
calculating, by the processor, the pressure value based on the first pressure and the second pressure.

8. A system, comprising:
a source vessel comprising a solid precursor;
a destination vessel fluidly coupled to the source vessel via a gas line such that a precursor gas sublimed from the solid precursor can flow from the source vessel to the destination vessel;
a pressure sensor coupled to the gas line configured to measure a pressure of the precursor gas flowing through the gas line;
a processor operably coupled to the pressure sensor; and
a tangible, non-transitory memory configured to communicate with the processor, the tangible, non-transitory memory having instructions stored thereon that, in response to execution by the processor, cause the processor to perform operations comprising:
measuring, by the processor and the pressure sensor, a pressure value of the precursor gas flowing through the gas line; and
determining, by the processor, a first amount of the solid precursor that flowed from the source vessel to the destination vessel based on the pressure value.

9. The system of claim 8, wherein the determining the first amount of the solid precursor comprises inputting, by the processor, the pressure value into a predetermined function.

10. The system of claim 9, wherein the predetermined function is based on a type of the solid precursor, a predetermined temperature, and a volume of the source vessel.

11. The system of claim 10, wherein the operations further comprise conducting, by the processor, a plurality of cycles to establish the predetermined function, wherein a cycle of the plurality of cycles comprises:
determining, by the processor, a starting weight of a test source vessel comprising the solid precursor;
heating, by the processor, the test source vessel comprising the solid precursor to the predetermined temperature to sublime a test portion of the solid precursor in the test source vessel to produce the precursor gas flowing through a test gas line to a test destination vessel;
measuring, by a test pressure sensor and the processor, a test pressure of the precursor gas flowing through the test gas line;
after ceasing the flowing the precursor gas, determining, by the processor, a first weight of the test source vessel;
comparing, by the processor, the first weight to the starting weight;
determining, by the processor, a transferred amount of the solid precursor based on the comparing the first weight to the starting weight;
plotting, by the processor, a data point based on the transferred amount and the measured test pressure on a pressure versus precursor transfer rate plot; and
repeating the cycle, wherein the first weight becomes the starting weight of the test source vessel, to receive and plot a plurality of data points.

12. The system of claim 11, wherein the operations further comprise creating, by the processor, the predetermined function from the plurality of data points.

13. The system of claim 12, wherein the predetermined function is linear.

14. The system of claim 10, wherein the operations further comprise heating, by the processor, the source vessel comprising the solid precursor to the predetermined temperature to sublime the solid precursor and produce the precursor gas flowing through the gas line.

15. The system of claim 8, wherein the destination vessel comprises a vessel body and a vessel lid coupled to the vessel body.

16. The system of claim 15, wherein the lid comprises a chemical inlet disposed in a central region of the lid.

17. The system of claim 15, further comprising a heater in thermal communication with the lid, and a cooling device in thermal communication with a base portion of the vessel body.

18. The system of claim 8, wherein the pressure sensor is a first pressure sensor, wherein the system further comprises a second pressure sensor coupled to the gas line, wherein the first pressure sensor is coupled to the gas line proximate the source vessel, and the second pressure sensor is coupled to the gas line proximate the destination vessel.

19. The system of claim 18, wherein the measuring the pressure value comprises:
receiving, by the processor, a first pressure from the first pressure sensor;
receiving, by the processor, a second pressure from the second pressure sensor; and
calculating, by the processor, the pressure value based on the first pressure and the second pressure.

20. A system, comprising:
a source vessel comprising a solid precursor;
a destination vessel fluidly coupled to the source vessel via a gas line such that a precursor gas formed from the solid precursor can flow from the source vessel to the destination vessel;
a processor; and
a tangible, non-transitory memory configured to communicate with the processor, the tangible, non-transitory memory having instructions stored thereon that, in response to execution by the processor, cause the processor to perform operations comprising:
determining, by the processor, a first amount of the solid precursor that flowed from the source vessel to the destination vessel based on a pressure value of the precursor gas in the gas line.
